(19) United States
(12) Patent Application Publication
(10) Pub. No.: US 2014/0175628 A1
(43) Pub. Date: Jun. 26, 2014

(54) COPPER WIRE BONDING STRUCTURE IN SEMICONDUCTOR DEVICE AND FABRICATION METHOD THEREOF

(71) Applicants: Hua Pan, Songjiang (CN); Yueh-Se Ho, Sunnyvale, CA (US); Jun Lu, San Jose, CA (US); Ming-Chen Lu, Songjiang (CN); Zhiqiang Niu, Santa Clara, CA (US)

(72) Inventors: Hua Pan, Songjiang (CN); Yueh-Se Ho, Sunnyvale, CA (US); Jun Lu, San Jose, CA (US); Ming-Chen Lu, Songjiang (CN); Zhiqiang Niu, Santa Clara, CA (US)

(21) Appl. No.: 13/724,006

(22) Filed: Dec. 21, 2012

(51) Int. Cl. H01L 23/495; H01L 23/00

(52) U.S. Cl. CPC H01L 23/49582; H01L 24/97
USPC 257/676; 438/113

(57) ABSTRACT

A semiconductor device comprises a first top electrode and a second top electrode at a front surface of the die, at least a Ni plating layer and an Au plating layer overlaying the Ni plating layer are formed on each of the first top electrode and the second top electrode. A copper clip attaches on the Au plating layer of the second top electrode. A gold (Au) stud bump is formed on the Au plating layer of the first top electrode with a copper wire connected on the stud bump. The Au stud bump is thicker than a thickness of the Au plating layer and thinner than a thickness of the copper clip to avoid copper wire NSOP (non-stick on pad) problem due to Ni plating layer diffusion during the solder reflow process in the copper clip attachment.

### FIELD OF THE INVENTION

This invention relates to the field of semiconductor devices, in particular to semiconductor device with a copper wire bonding structure in a clip package and a fabrication method thereof.

### DESCRIPTION OF THE RELATED ART

In clip package technology of semiconductor device, a metal plating layer is firstly formed on a corresponding electrode of a die, then, a copper clip is mounted on the metal plating layer forming an electrical connection between the die electrode and the other devices.

Copper plating is not used due to expensive manufacturing cost caused by its large thickness. However, in prior art, copper plating is replaced by Ni/Au (nickel/gold) plating, Ni/Pd (nickel/palladium) plating or Ni/Pd/Au (nickel/palladium/gold) plating.

In a semiconductor device as shown in FIG. 1, the bottom electrode (such as drain) of die 1′, covered with a back metal layer 13′, is attached onto a lead frame 41′. The die 1′ also includes a plurality of top electrodes (such as gate and source) and aluminum (Al) metal layers 11′ and 12′ are formed on each top electrode of the die with a plating layer formed on each of the aluminum metal layers 11′ and 12′. If the plating layer is Ni/Au plating for example, Ni plating layers 21′ and 22′ are firstly formed on the metal layers 11′ and 12′ respectively, then Au plating layers 31′ and 32′ are formed on the Ni plating layers 21′ and 22′ respectively. A passivation layer 20′ is formed between the two adjacent top electrodes (including the above Al metal layer and Ni/Au plating layers) on the die 1′ for an electrical insulation between the electrodes (including Al metal layer and Ni/Au plating layers). Thus, a copper clip 50′ is firmly connected to the Au plating layer 32′ of one top electrode and a copper wire 60′ is connected to the Au plating layer 31′ in a wire bonding mode. As such, the top electrodes are electrically connected to other portion of lead frames 42′ and 43′ or to the external device through the clip 50′ and the wire 60′ respectively.

FIG. 2 is a flow diagram of the fabrication method of the semiconductor device as shown in FIG. 1. In step 101, a wafer including a plurality of die 1′ is provided with each die including a back metal layer 13′ formed on its bottom electrode, Al metal layers 11′ and 12′ and Ni/Au plating layers 21′, 22′, 31′ and 32′ formed on its top electrode correspondingly, and a passivation layer 20′ formed between the top electrodes as shown in FIG. 1. In step 102, the wafer is sawed to separate individual dies 1′. In step 103, the back metal layer 13′ of the die 1′ is mounted on a lead frame 41′ via a solder 71′. In step 104, a copper clip 50′ is mounted on the Au plating layer 32′ formed at the top electrode of the die 1′ via solder 73′ and on a pin 42′ via a solder 72′. In step 105, the solder is reflowed at high temperature and then cleaned. In step 106, a copper wire 60′ is bonded to the Au plating layer 31′ formed at top electrodes of the die 1′ and to a pin 43′. Finally, in step 107, the semiconductor devices are packaged in a housing 80′ and then singulated into individual semiconductor packages.

However, during the solder reflow at a high temperature of above 300° C. (such as 380° C.), nickel of the Ni plating layer is diffused to the top surface of the Au plating layer, which can cause reliability issue as the copper wire is not bonded on the Au plating layer, or even worse, the Ni plating layer diffusion causes a serious NSOP (non-stick on pad) problem, resulting in fault connection of the copper wire due to insufficient bonding force. Such problem not only arises in Ni/Au plating layers but also in Ni/Pd and Ni/Pd/Au plating layers. In addition, during high temperature solder reflow, contamination on the die surface due to the volatilization of the solder paste can also induce the NSOP problem that affects the quality of the finished product of the semiconductor device.

### BRIEF DESCRIPTION OF THE DRAWINGS

FIG. 1 is a cross-sectional schematic diagram of a conventional semiconductor device, wherein a copper wire is bonded on the Au plating layer on the surface of the die;

FIG. 2 is a flow diagram of a fabrication method of the conventional semiconductor device as shown in FIG. 1.

FIG. 3 is a cross-sectional schematic diagram of a semiconductor device of the present invention, wherein the copper wire is bonded on the Au stud bump formed on the surface of the die;

FIG. 4 is a cross-sectional schematic diagram of the structure in the dotted line of FIG. 3

FIG. 5 is a flow diagram of the fabrication method of the semiconductor device as shown in FIG. 3

FIGS. 6-10 are cross-sectional schematic diagrams illustrating corresponding steps of the fabrication method shown in FIG. 5.

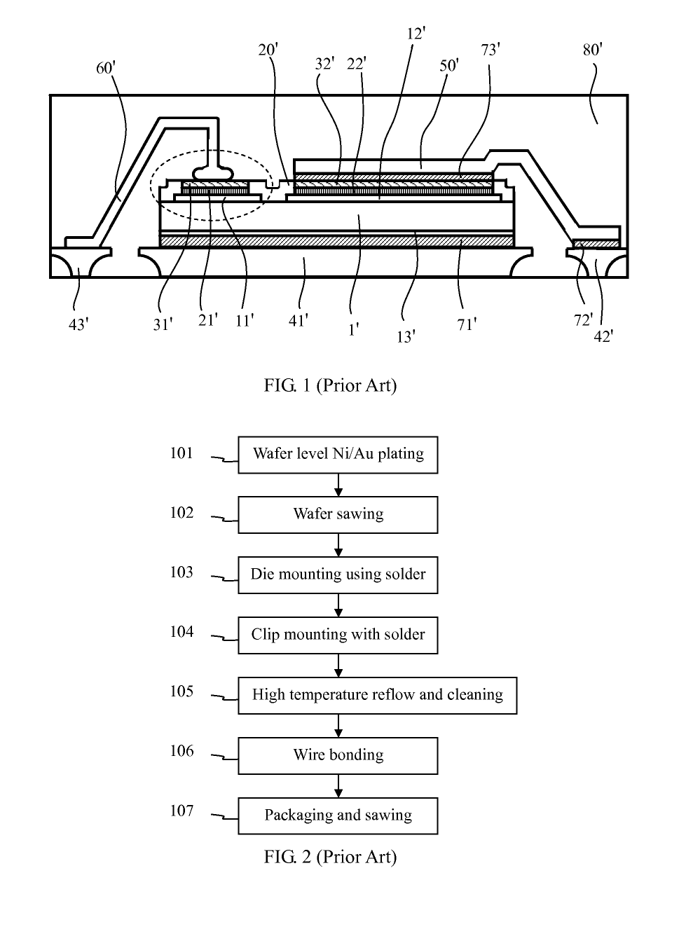

### DETAILED DESCRIPTION OF THE PREFERRED EMBODIMENTS

The mode of carrying out the invention is described hereunder by combining attached drawings.

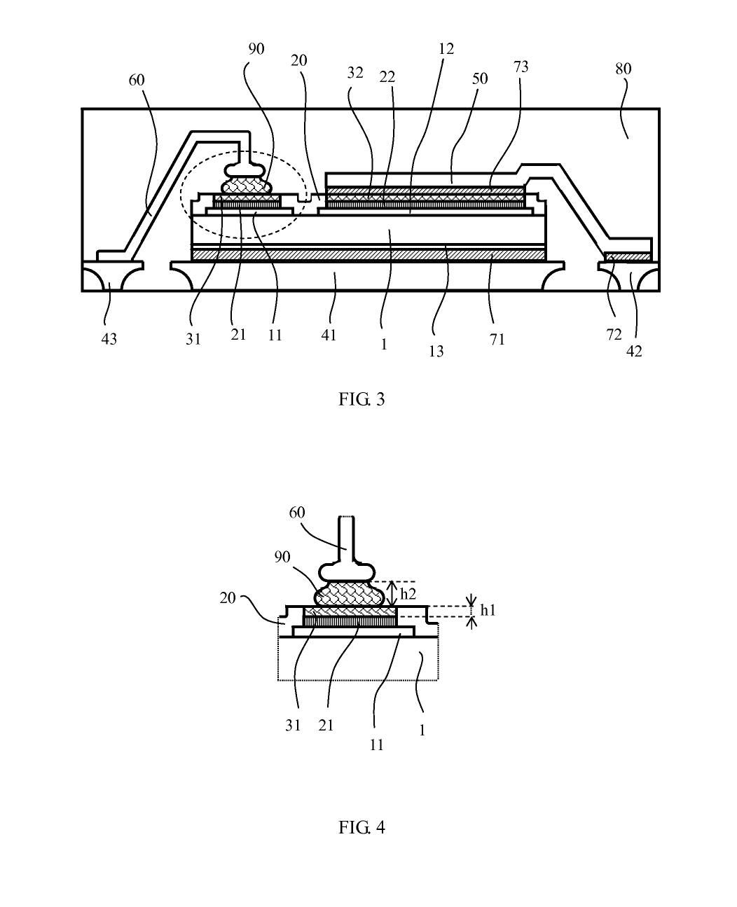

As shown in FIG. 3, a semiconductor device comprises a die 1 that includes a bottom electrode at its back surface with a back metal layer 13 formed on the bottom electrode. The back metal layer 13 of the die 1 is attached on the surface of a lead frame 41 by a first solder layer 71.

The die 1 also includes a first top electrode and a second top electrode at its front surface. An aluminum (Al) metal layer 11, a first nickel plating layer 21, and a second gold (Au) plating layer 31 are formed on the first top electrode in sequence. In addition, an Al metal layer 12, a first nickel (Ni) plating layer 22 and a second Au plating layer 32 are also formed on the second top electrode in sequence. A passivation layer 20 is formed on the surface of the die 1 to separate the first top electrode and the second top electrode from the metal layers 11 and 12 as well as separate the first plating layer 21 and 22 from the second plating layer 31 and 32, thereby the first top electrode is electrically insulated from the second top electrode. A second solder layer 73 is formed on the second Au plating layer 32 of the second top electrode for connecting one end of the Cu clip 50 and a third solder layer 72 is formed on the first pin 42 for connecting the other end of the clip 50, thus forming an electrical connection between the second top electrode of the die 1 and the external device.

Referring to FIG. 3 and FIG. 4, an Au stud bump 90 is further formed on the second Au plating layer 31 of the first top electrode of the die 1 with the stud bump 90 being thicker than the second Au plating layer 31. In a preferred embodiment, the stud bump 90 is thinner than the clip 50. The Au stud bump 90 is combined with the second plating layer 31 together as a buffer layer for copper wire bonding, such that one end of the copper wire 60 is connected to the Au stud bump 90, and the other end of the copper wire 60 is connected to the second pin 43; therefore, the first top electrode of the die 1 is electrically connected to the external device. Finally, a housing 80 of a packaging material is formed on the surface of the semiconductor structure.

In a preferred embodiment, the stud bump 90 with a thickness h2 of 0.5-5 mil is formed on the second Au plating layer 31 of the first top electrode by the conventional ball bonding technology with the Au wire having a diameter of 1-2 mil. The thickness of the stud bump 90 (h2=0.5-5 mil) is greater than the thickness of the second Au plating layer 31 (h1=10-100 nm) on the first top electrode but smaller than the thickness of the clip 50. During reflow soldering at high temperature, the first Ni plating layer 21 at the first top electrode cannot diffuse to the top of the stud bump 90; therefore, the copper wire 60 is reliably connected to the Au stud bump 90 during the later copper wire bonding.

In addition, during reflow soldering at high temperature, if the solder paste is volatilized to contaminate the surface of the Au stud bump 90, it is very easy to clean due to the rough surface of the thick Au stud bump 90, thus the copper wire bonding is enhanced.

In a preferred embodiment, the die 1 is a metal-oxide semiconductor field effect transistor (MOSFET) die, where the bottom electrode of the die 1 is the drain, the first top electrode is the gate and the second top electrode is the source or where the bottom electrode of the die 1 is the source, the first top electrode is the gate, and the second top electrode is the drain.

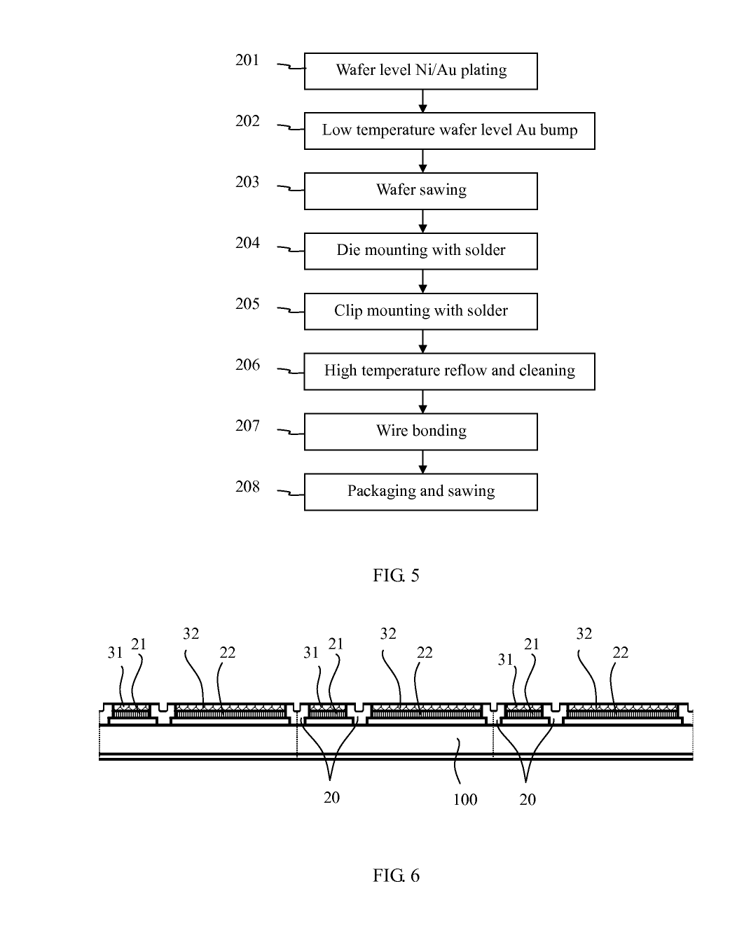

The flow diagram shown in FIG. 5 and the cross-sectional schematic diagram shown in FIG. 6 to FIG. 10 illustrate a fabrication method for the semiconductor device shown in FIG. 3.

Referring to FIG. 6 and step 201 of FIG. 5, a wafer 100 including a plurality of dies is provided. As described above, each die includes a back metal layer 13 formed on the bottom electrode; an Al metal layer 11, a first Ni plating layer 21 and a second Au plating layer 31 formed on a first top electrode in sequence; an Al metal layer 12, a first Ni plating layer 22 and a second Au plating layer 32 formed on the second top electrode in sequence. A passivation layer 20 is formed between two adjacent top electrodes of the wafer, i.e., between the first top electrode and the second top electrode of each die, and between one top electrode of one die and the top electrode of another adjacent die, for electrical insulation the top electrodes, the Al metal layer and Ni/Au plating layer. For example, the first Ni plating layer 21 and 22 and the second Au plating layer 31 and 32 can be formed by electroless plating layer with non-cyanide gold. Preferably, the thickness h1 of the second Au plating layer 31 is 10-100 nm.

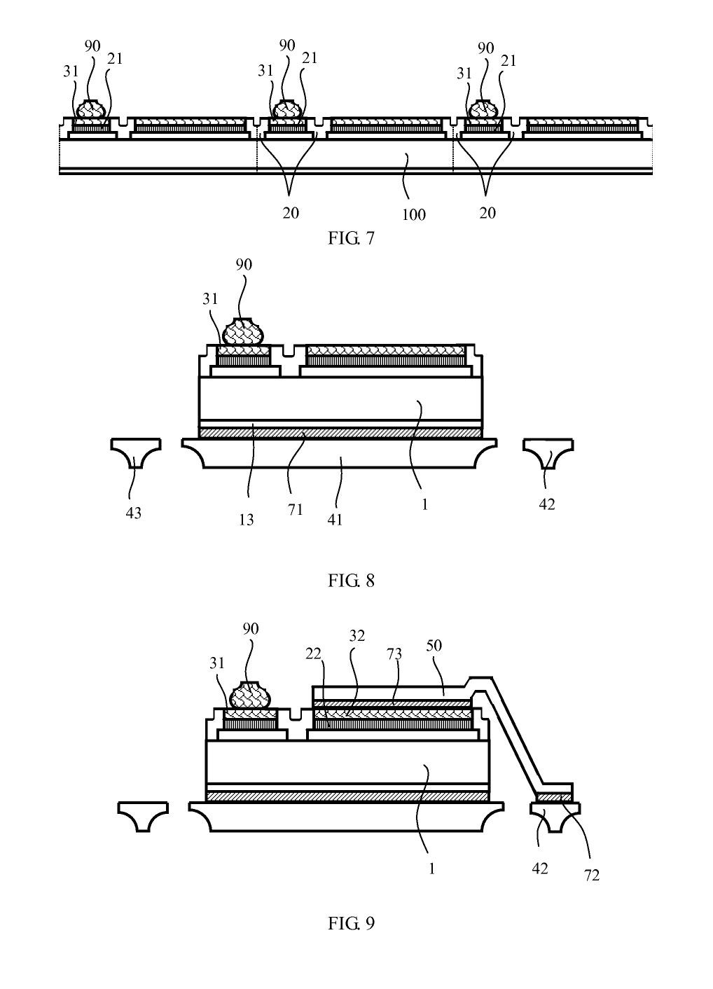

Referring to FIG. 7 and the step 202 of FIG. 5, an Au stud bump 90 is formed on each second Au plating layer 31 of the first top electrode. For example, the stud bump 90 with a thickness h2 of 0.5-5 mil is formed on the first plating layer 31 by ball bonding technology with an Au wire having a diameter of 1-2 mil, such that the thickness h2 of the stud bump 90 is greater than the thickness h1 of the second Au plating layer 31.

Traditionally, forming gold bumps by Au wire bonding method is performed at a temperature of above 200° C. In the process of the present invention, the stud bumps 90 are formed on all dies of the wafer by Au wire bonding at a temperature that is controlled of lower than 160° C., during the process of forming the stud bumps 90 starting on the first die on the wafer 100 to the last die for about 4 hours to avoid the first Ni plating layer 21 and 22 diffusing to the surface of the second Au plating layer 31 and 32 and the Au stud bump 90. The process of the present invention is performed at a wafer level. However, for the sake of clarity, FIG. 7 to FIG. 10 only show the following steps on an individual die.

Referring to FIG. 7 to FIG. 8 and step 203 of FIG. 5, individual dies 1 are singulated by sawing the wafer 100 at the scribe lines at the passivation layer 20 between two adjacent dies 1. Referring to FIG. 8 and step 204 of FIG. 5, a lead frame includes a die paddle 41, a first pin 42 and the second pin 43, which are separated from each other. The back of the die 1 is attached on the die paddle 41 via a first solder layer 71 formed between the back metal layer 13 of the die 1 and the surface of the die paddle 41. Thus, the bottom electrode of the die 1 can be electrically connected to the external devices through the die paddle 41.

Referring to FIG. 9 and step 205 of FIG. 5, a second solder layer 73 is formed on the second Au plating layer 32 of the second top electrode of the die 1 and one end of a copper clip 50 is attached on the second top electrode of the die 1 through the second solder layer 73. Furthermore, a third solder layer 72 is formed on the first pin 42 and the other end of the copper clip 50 is attached on the third solder layer 72. Thus, the second top electrode of die 1 can be electrically connected to the external devices through the first pin 42. In a preferred embodiment, the stud bump 90 is thinner than the clip 50.

In step 206, the reflow soldering is performed at a temperature above 300° C. (such as 380° C.) to ensure the die 1 firmly connected to the die paddle 41 and the two ends of the copper clip 50 firmly connected to the second plating layer 32 of the second top electrode and the first pin 42 respectively. Then, the surface of the die 1 is cleaned to remove the contamination caused by the volatilization of the solder paste during the reflow soldering.

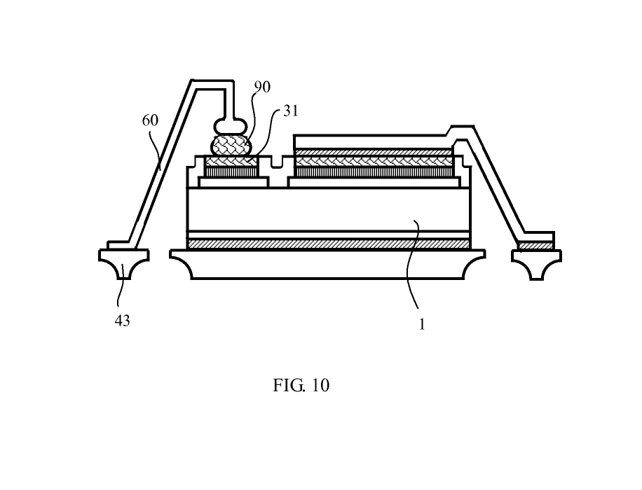

Referring to FIG. 10 and step 207 of FIG. 5, the Au stud bump 90 on the first top electrode of the die 1 and the second plating layer 31 together form a buffer layer for wire bonding of a copper wire 60. One end of the copper wire 60 is connected to the Au stud bump 90 and the other end of the copper wire 60 is connected to the second pin 43. Thus, the first top electrode of die 1 can be electrically connected to the external devices through the second pin 43.

Finally, referring to FIG. 3 and step 208 of FIG. 5, each individual semiconductor device is packaged in one plastic package housing 80 and then singulated. In the invention, the stud bump 90 is formed by Au wire bonding on the second Au plating layer 31 on the surface of the die 1 at a temperature below 160° C.; therefore, the first Ni plating layer 21 is diffused slowly. The Au stud bump 90 and the second Au plating layer 31 form a thicker buffer layer; therefore, during reflow soldering at high temperature, the first Ni plating layer 21 is prevented from diffusing to the second Au plating layer 31 and stud bump 90. Furthermore, NSOP problem of connecting the copper wire 60 to the Au stud bump 90 is effectively solved, thereby ensuring the connection reliability of the copper wire 60 as well as the product quality of the semiconductor device.

In addition, as mentioned above, the Ni/Au plating layers formed on the Al metal layers 11 and 12 of the first top electrode and the second top electrode of the die 1 can be replaced with Ni/Pd plating layers or Ni/Pd/Au plating layers. In this case, the Au stud bump 90 is formed on the uppermost of the plating layer surface and also can effectively prevent the Ni layer from diffusing to the surface of the other plating layer or on the stud bump 90 during reflow soldering at high temperature.

The above detailed descriptions are provided to illustrate specific embodiments of the present invention and are not intended to be limiting. Numerous modifications and variations within the scope of the present invention are possible. The present invention is defined by the appended claims.

1. A semiconductor device comprising:
a die attached on a die paddle of a lead frame, wherein a first top electrode and a second top electrode separated from each other are arranged at a front surface of the die, at least a first plating layer and a second plating layer overlaying the first plating layer are formed on each of the first top electrode and the second top electrode;
a copper clip having a first end attached on the second plating layer of the second top electrode and a second end attached on a first pin of the lead frame; and
a gold (Au) stud bump formed on the second plating layer of the first top electrode, a copper wire having a first end connected on the stud bump and a second end connected to a second pin of the lead frame, wherein the Au stud bump is thicker than a thickness of the second plating layer and thinner than a thickness of the copper clip.

2. The semiconductor device of claim 1, wherein the first plating layer is a nickel layer and the second plating layer is an Au layer or a palladium layer.

3. The semiconductor device of claim 1, wherein the first plating layer is a nickel layer, the second plating layer is an Au layer, and a palladium intermediate plating layer is further formed between the first plating layer and the second plating layer.

4. The semiconductor device of claim 1, wherein an aluminum metal layer is formed on the first top electrode and the second top electrode before the first plating layer is formed on the first top electrode and the second top electrode, wherein the first plating layer is formed on the aluminum metal layer.

5. The semiconductor device of claim 4, wherein a passivation layer is formed at the front surface of the die in spaces between the aluminum metal layer, the first plating layer and the second plating layer on the first top electrode and the second top electrode, so that the first top electrode is electrically insulated from the second top electrode.

6. The semiconductor device of claim 1, wherein a bottom electrode is formed at a back surface of the die, a back metal layer is formed on the bottom electrode and is attached on the die paddle through a first solder layer disposed on a surface of the die paddle.

7. A fabrication method for a semiconductor device comprising the steps of:
a) forming a plurality of dice on a wafer, wherein a plurality of top electrodes separated from each other are formed at a front surface of each die, and at least a first plating layer and a second plating layer are formed on each top electrode with the second plating layer overlaying the first plating layer; the top electrodes of each die comprise at least a first top electrode and a second top electrode;
b) forming a plurality of Au stud bumps on the wafer, wherein each Au stud bump is correspondingly formed on the second plating layer on the first top electrode of each die;
c) singulating individual die by cutting the wafer;
d) attaching a back surface of the die on a die paddle of a lead frame by a first solder layer;
e) connecting a copper clip on the second plating layer of the second top electrode of the die by a second solder layer;
f) performing reflow soldering then cleaning the surface of the die;
g) connecting a copper wire to the Au stud bump of the first top electrode of the die; and
h) packaging the die to form individual semiconductor device.

8. The fabrication method of claim 7, wherein a passivation layers are formed at the front surface of the wafer for electrical insulating the first plating layer and the second plating layer of the two adjacent top electrodes, and wherein each individual die is singulated by cutting through the passivation layer between adjacent dice.

9. The fabrication method of claim 7, wherein the second plating layer has a thickness of 10-100 nm and is formed on the first top electrode with a non-cyanide gold by the electroless plating layer technology.

10. The fabrication method of claim 9, wherein the Au stud bump has a thickness of 0.5-5 mil and is formed by ball bonding technology with an Au wire having a diameter of 1-2 mil, and wherein the Au stud bump is thicker than the second plating layer formed at the first top electrode.

11. The fabrication method of claim 7, wherein the temperature is below 160° C. during the formation of the Au stud bump on the die.

12. The fabrication method of claim 7, wherein one end of the clip is attached on the second solder layer, and another end of the clip is attached on a third solder layer disposed on a surface of a first pin of the lead frame.

13. The fabrication method of claim 7, wherein the reflow soldering is performed at a temperature above 300° C.

14. The fabrication method of claim 7, wherein one end of the copper wire is connected to the Au stud bump formed on the die and another end of the copper wire is connected to a second pin of the lead frame.
